(19) United States
(12) Patent Application Publication
(10) Pub. No.: US 2026/0324007 A1
(43) Pub. Date: Oct. 15, 2026

(54) AN ELECTRONIC DEVICE AND METHOD OF FORMING AN ELECTRONIC DEVICE

(71) Applicant: NEWSOUTH INNOVATIONS PTY LIMITED, Sydney, New South Wales (AU)

(72) Inventors: Jing-Kai HUANG, Sydney, New South Wales (AU); Junjie SHI, Sydney, New South Wales (AU); Ji ZHANG, Sydney, New South Wales (AU); Sean Suixiang LI, Sydney, New South Wales (AU)

(21) Appl. No.: 18/682,758

(22) PCT Filed: Aug. 12, 2022
(86) PCT No.: PCT/AU2022/050884

§ 371 Date: Feb. 9, 2024

(30) Foreign Application Priority Data
Aug. 12, 2021 (AU) 2021902514
Feb. 17, 2022 (AU) 2022900344

(51) Int. Cl. H01L 29/786; H01L 23/14; H01L 27/12; H01L 29/22; H01L 29/24; H01L 29/26; H01L 29/66

(52) U.S. Cl. CPC H10D 30/6758; H10D 30/6755; H10D 86/0214; H10D 86/411; H10D 86/60; H10D 99/00; H10W 70/695; H10W 70/698; H10D 62/80; H10D 62/86

(57) ABSTRACT

An electronic device comprising: a non-conductive solid-state substrate; a plurality of electrodes; at least one high-k dielectric membrane, wherein the dielectric membrane is formed as a free-standing membrane; and at least one semiconductor channel layer; wherein the dielectric membrane and semiconductor channel layer form a van der Waals interface between the dielectric mem brane and the semiconductor channel layer. Associated methods and devices formed from the methods are also described.

### RELATED APPLICATIONS

This application is a 35 U.S.C. § 371 national stage application of PCT Application No. PCT/AU2022/050884, filed on Aug. 12, 2022, which itself claims priority from Australian Patent Application No. 2022900344, filed on Feb. 17, 2022, and also claims priority to Australian Patent Application No. 2021902514, filed on Aug. 12, 2021, the contents of all of which are incorporated herein by reference in their entireties. The above-referenced PCT International Application was published in the English language as International Publication No. WO 2023/015356 A1 on Feb. 16, 2023.

### TECHNICAL FIELD

The present invention relates generally to an electronic device and a method of forming an electronic device.

### BACKGROUND

Producing electronic devices has inherent problems with the constant need to continually meet reduced size requirements.

For example, metal oxide semiconductor field effect transistor (MOSFET) technology's success has relied on the ability to follow Moore's Law and shrink the geometry of the devices down to nanoscale in order to achieve high speed signal processing.

A key challenge is to produce so called “two-dimensional” semiconductor devices with high-k dielectric materials without causing deterioration in the interface between the semiconductor channel layer and the high-k dielectric layer.

### SUMMARY

It is an object of the present invention to substantially overcome, or at least ameliorate, one or more disadvantages of existing arrangements.

Disclosed are arrangements which seek to address the above problems by providing a method of producing and/or forming an electronic device, e.g. an FET (field effect transistor) device, that has an improved interface between the semiconductor channel layer and the high-k dielectric layer and also the interface between the high-k dielectric layer and the gate electrode.

According to a first aspect of the present disclosure, there is provided an electronic device comprising: a non-conductive solid-state substrate; a plurality of electrodes; at least one high-k dielectric membrane, wherein the dielectric membrane is formed as a free standing membrane; and at least one semiconductor channel layer; wherein the dielectric membrane and semiconductor channel layer form a van der Waals interface between the dielectric membrane and the semiconductor channel layer.

According to a further aspect of the present disclosure, there is provided a method of method of forming at least a portion of an electronic device from a layered sample, wherein the layered sample comprises a membrane stack comprising a support layer formed on a high-k dielectric membrane, the membrane stack formed on a sacrificial layer, and the sacrificial layer formed on a temporary substrate, the method comprising the steps of, at a low temperature of between 0° C. and 150° C.: immersing the layered sample into a liquid for removing the sacrificial layer and separating the temporary substrate from the membrane stack; removing the membrane stack from the liquid; positioning the membrane stack on a target substrate, wherein the target substrate comprises electrodes; and removing the support layer from the membrane stack leaving the dielectric membrane formed on the target substrate to form at least a portion of the electronic device.

An electronic device formed by the above method steps.

Other aspects are also disclosed.

### BRIEF DESCRIPTION OF THE DRAWINGS

At least one embodiment of the present invention will now be described with reference to the drawings and appendices, in which:

FIG. 1 shows a diagrammatic representation of the steps for depositing a high-k dielectric material (or membrane) according to the present disclosure;

FIG. 2 shows a diagrammatic representation of the steps for transferring the high-k dielectric membrane to a target substrate according to the present disclosure;

FIG. 3 shows a diagrammatic representation of the top view of the target substrate according to the present disclosure;

FIG. 4 shows a diagrammatic representation of process steps for forming a semiconductor channel layer with a polymer support layer according to the present disclosure;

FIG. 5 shows a diagrammatic representation of process steps for integrating the monolayer stack onto the dielectric membrane according to the present disclosure;

FIGS. 6A and 6B show diagrammatic representations of further process steps for forming an electronic device according to the present disclosure;

FIGS. 7A to 12 show an example of the process steps for forming a dielectric membrane on a solid-state substrate according to the present disclosure;

FIG. 13 shows an example of a pulsed laser deposition (PLD) system for use in depositing a dielectric membrane according to the present disclosure;

FIG. 14 shows an example of a molecular beam epitaxy (MBE) system for use in depositing a dielectric membrane according to the present disclosure;

FIG. 15 shows a photo of a dielectric membrane according to the present disclosure;

FIGS. 16A and 16B show an atomic force microscopy image of an as-grown SrTiO₃ (STO) film according to the present disclosure;

FIG. 17A shows an XRD Φ-scan of (103) reflections of 80 u.c. STO film transferred on Si substrate according to the present disclosure;

FIG. 17B shows a reciprocal space mapping (RSM) of transferred 80 u.c. STO film around (002), (103), and (013) planes according to the present disclosure;

FIG. 18A shows voltage-dependent capacitance density (C-V) for metal-insulator-metal (MIM) devices of 40 u.c. and 20 u.c. free-standing STO membranes at four different frequencies according to the present disclosure;

FIG. 18B shows t/ε_{eff}, where t is the thickness of the free-standing STO membrane, and ε_{eff} is its effective permittivity, and equivalent oxide thickness (EOT) as a function of various STO thicknesses measured from MIM capacitors according to the present disclosure;

FIG. 19A shows electric field-dependent leakage current density of free-standing STO membranes with various unit-cell thicknesses according to the present disclosure;

FIG. 19B shows breakdown characteristics of STO layers with various thicknesses according to the present disclosure;

FIG. 20A shows optical micrograph of batch-fabricated FET arrays according to the present disclosure;

FIG. 20B shows a cross-sectional scanning transmission electron microscope (STEM) image and the corresponding energy-dispersive X-ray spectroscopy (EDS) mapping obtained in the contact-channel area according to the present disclosure;

FIG. 21A displays transfer characteristics (I_{D}-V_{G}) of monolayer MoS₂ FET with a structure as shown in FIG. 6B according to the present disclosure;

FIG. 21B shows output characteristics (I_{D}-V_{D}) of the device of FIG. 6B according to the present disclosure;

FIG. 21C shows scatter distribution of recorded ON/OFF current ratios and subthreshold swing (SS) values, and statistical histogram of SS from 50 devices according to the present disclosure;

FIG. 22 shows scanning electron microscope (SEM) image of a device with a channel length of 35 nm according to the present disclosure;

FIG. 23A shows I_{D}-V_{G} characterization of the device shown in FIG. 22 according to the present disclosure;

FIG. 23B shows I_{D}-V_{D} output curves of the device shown in FIG. 22 according to the present disclosure;

FIG. 24A shows a photograph of experiment setup for mechanical bending of MoS₂ FETs according to the present disclosure;

FIG. 24B shows measured transfer characteristics of the device under flat, strained, and resumed conditions according to the present disclosure;

FIG. 25 shows a further example of process steps used to manufacture a dual-gate FET device incorporating a free-standing membrane according to the present disclosure;

FIGS. 26A and 26B show the process steps for forming top gate electrodes for the dual-gate FET device;

FIG. 27 shows a magnified portion of the FET device shown in FIGS. 26A and 26B according to the present disclosure;

FIG. 28 shows a further example of process steps used to manufacture a gate-all-around (GAA) device according to the present disclosure;

FIG. 29A shows a front view and side view of the gate-all-around (GAA) structure according to the present disclosure.

FIG. 29B shows a side view of the gate-all-around (GAA) structure with source and drain electrodes according to the present disclosure.

FIG. 29CB shows a side view of the gate-all-around (GAA) structure with selectively etched portions of the high-k dielectric according to the present disclosure.

FIG. 30A shows a side view of the gate-all-around (GAA) structure with gate electrodes according to the present disclosure;

FIG. 30B shows a front view of the device in FIG. 30A according to the present disclosure;

FIG. 31 shows a three-dimensional perspective view of a gate-all-around device according to the present disclosure.

### DETAILED DESCRIPTION INCLUDING BEST MODE

It is to be noted that the discussions contained in the “Background” section relate to discussions of documents or devices which form public knowledge through their respective publication and/or use. Such should not be interpreted as a representation by the present inventor(s) or the patent applicant that such documents or devices in any way form part of the common general knowledge in the art.

Where reference is made in any one or more of the accompanying drawings to steps and/or features, which have the same reference numerals, those steps and/or features have for the purposes of this description the same function(s) or operation(s), unless the contrary intention appears.

The term “monolayer” is understood to be a “two-dimensional” layer, or an “atomic thickness” layer having a thickness of a single molecule with atomic flat surfaces. One example of a monolayer described herein includes a chemical vapour deposition (CVD) deposited monolayer forming a semiconductor channel layer, e.g. MoS₂. Although the example described uses CVD techniques to deposit the monolayer, other suitable deposition techniques for depositing or forming a monolayer may also be used, such as physical vapour deposition (PVD), plasma enhanced chemical vapour deposition (PECVD), metal organic chemical vapour deposition (MOCVD), atomic layer deposition (ALD) and molecular beam expitaxy (MBE). Also, other suitable materials as described herein may be used to form the semiconductor channel layer.

The term “room temperature” is understood to be a temperature within a range of 0° C. and 40° C. More preferably, “room temperature” is understood to be a temperature within a range of 10° C. and 25° C. More preferably, “room temperature” is understood to be a temperature within a range of 15° C. and 25° C.

The term “high-k” in reference to the dielectric membrane described herein is understood to be a reference to the dielectric constant of the dielectric membrane. The term “high-k” is preferably understood to be a dielectric constant of greater than 10. For example, “high-k” is preferably understood to be a dielectric constant in the range from 10.00 to 24,000.00.

The phrase “free-standing” in reference to the dielectric membrane described herein is understood to mean “capable of not being attached to or supported by another structure” or “capable of existence on its own away from other elements”. Although examples are described herein where a “free-standing” membrane is always attached to another layer during processing, it will be understood that the “free-standing” membrane may, for example, be a membrane that may be detached from the other layers to be manipulated, transferred or processed on its own away from other elements, layers or components of the electronic device.

The term “unit cell” is understood to mean the smallest group of atoms which has the overall symmetry of a crystal, and from which the entire lattice can be built up by repetition in three dimensions.

The term “transparent” is understood to mean allowing light to pass through so that objects behind can be distinctly seen.

The term “flexible” is understood to mean capable of bending or deforming easily with minimal effects on the device performance.

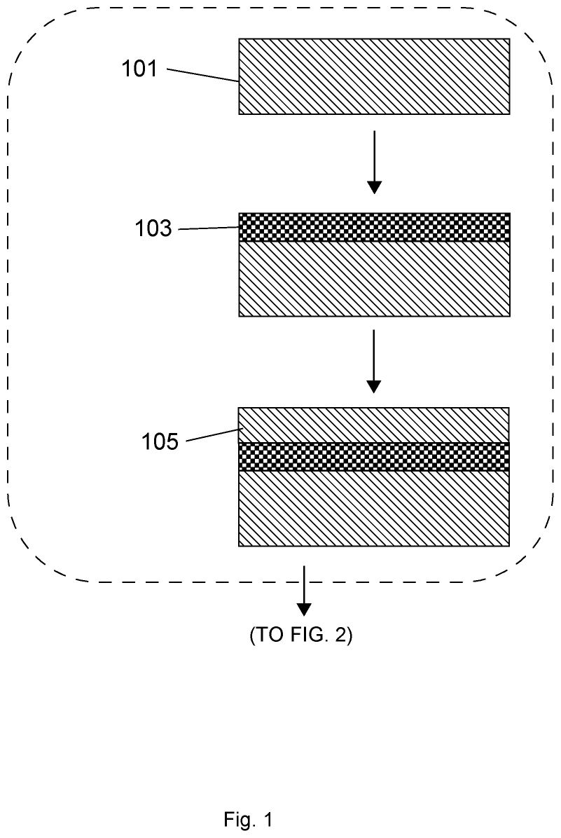

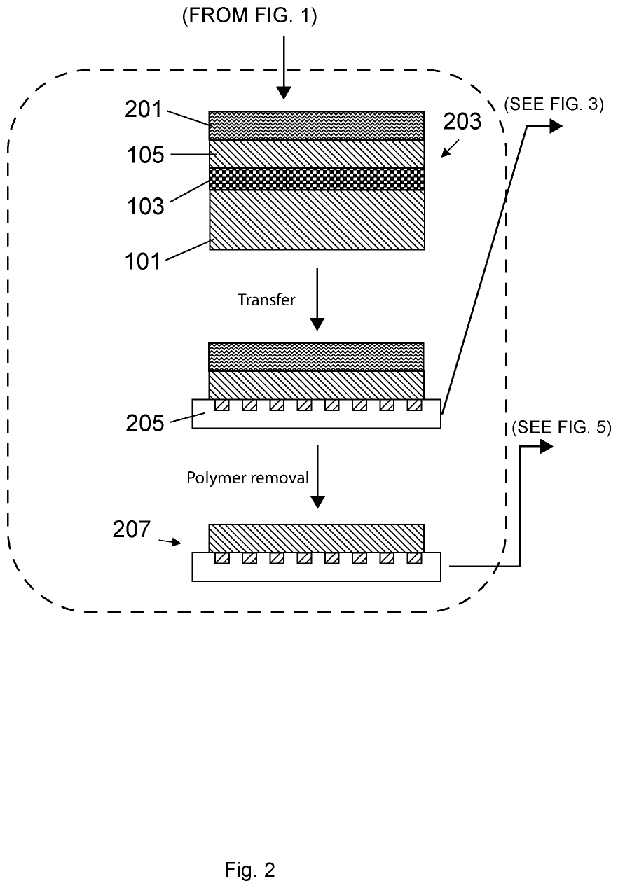

FIGS. 1 to 6B show the process steps for forming an electronic device, which in this example is a field effect transistor (FET) device.

FIG. 1 shows a diagrammatic representation of the steps for depositing a high-k dielectric membrane (e.g. a film or layer).

An SrTiO₃ (STO) temporary substrate 101 is provided and a sacrificial layer 103 of Sr₃Al₂O₆ (SAO) is deposited on to the temporary substrate 101. After the sacrificial layer has been deposited, the high-k dielectric membrane (SrTiO₃) 105 is grown (or deposited) on to the SAO sacrificial layer 103. The high-k dielectric membrane 105 may also be the other materials including BaTiO₃, BiTiO₃, BiFeO₃, LaAlO₃, CaMnO₃, KTaO₃, BaZrO₃, PbZrₓTi₍₁₋ₓ₎O₃, Al₂O₃, CeO₂, MgO, TiO₂, HfO₂, ZrO₂, Ta₂O₅, La₂O₃, Y₂O₃ or Ga₂O₃, AlN and TiN or their modified compounds, other oxides or nitrides. It can also be the bilayered or multilayered freestanding superlattice membrane that consists of two or more compounds listed above. The high-k membrane 105 can also be formed by mechanically or physically stacking the individual membranes listed above. Physically stacking is intended to mean that there is no chemical bonding between the individual membranes, and as such, distinguishes them from a superlattice structure.

FIG. 2 shows an example of the steps for transferring the high-k dielectric membrane to a target substrate, which is a non-conductive solid-state substrate having at least one electrode.

A polymer support layer 201 is formed on the high-k dielectric membrane 105 to form a layered sample 203. For example, the polymer support layer is spin coated onto the dielectric membrane. Other suitable techniques for placing the polymer support layer on the dielectric membrane may also be used, such as printing technologies including slot die printing, roller printing and screen printing. Also, coating technologies may be used including dip coating, spray coating and thermal deposition.

In this document, the combination of the polymer support layer 201 and the dielectric membrane 105 is referred to as the “membrane stack”. The membrane stack is transferred to and positioned on the target substrate 205. According to one example, the transfer of the membrane stack to the target substrate occurs by removing (e.g. dissolving) the sacrificial layer in de-ionised water, which separates the temporary substrate 101 from the membrane stack. The membrane stack is then removed from the de-ionised water and positioned on the target substrate. This transfer process is described in more detail herein. For example, the transfer process is carried at a low temperature between 0° C. and 150° C., or at room temperature.

The polymer support layer 201 is then removed from the membrane stack, leaving the high-k dielectric membrane 105 positioned on the target substrate 205 to form a portion 207 of the electronic device, which is used in a further process described herein to form the electronic device.

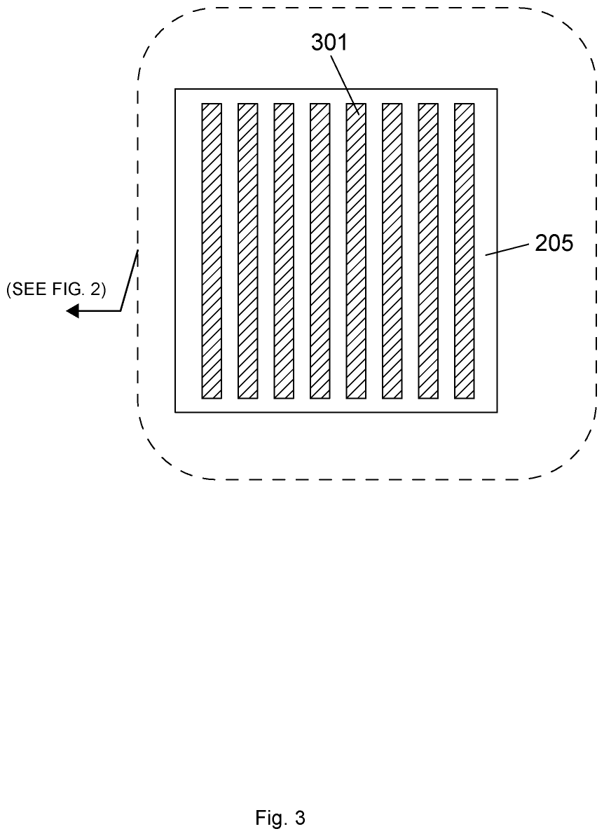

FIG. 3 shows a diagrammatic representation of the top view of the target substrate 205, on which the pre-patterned metal electrodes 301 are shown positioned on the target substrate 205. In this example, the electrodes are gate electrodes for forming a field effect transistor (FET) electronic device. However, it will be understood that the target substrate may be formed using one or more other types of electrodes for use in the electronic device.

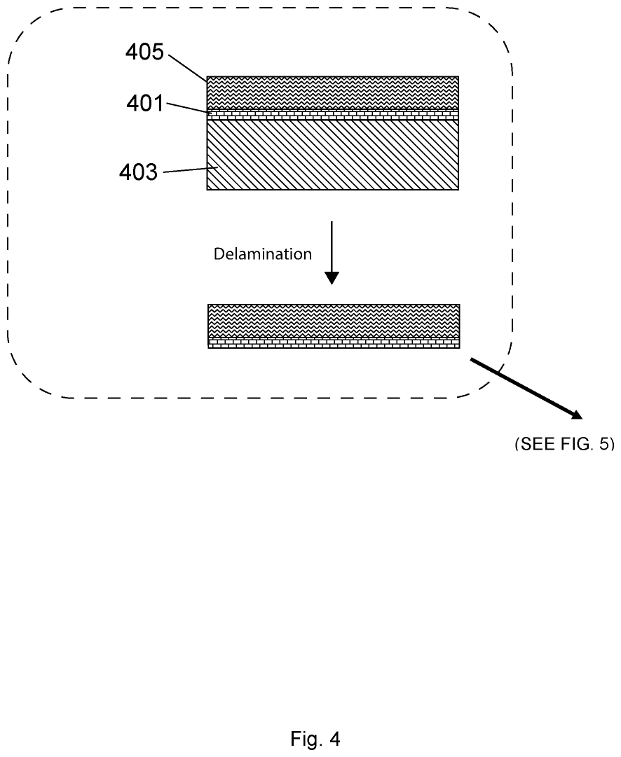

FIG. 4 shows a diagrammatic representation of process steps for forming a semiconductor channel layer with a polymer support layer.

As shown in FIG. 4, a semiconductor channel layer 401 is deposited on a further temporary substrate of Al₂O₃ 403. A polymer support layer 405 is deposited on to the semiconductor channel layer 401. In this document, the combination of the polymer support layer 405 and the semiconductor channel layer 401 is referred to as the “monolayer stack”.

Subsequently, the further temporary substrate 403 is delaminated from the monolayer stack by using alkali metal or alkaline earth metal hydroxide solution to intercalate the interface between temporary substrate 403 and semiconductor channel layer 401. The concentration of sodium hydroxide solution is from 10⁻³ M to 1 M. The monolayer stack is then transferred, at a low processing temperature (for example, between 0° C. and 150° C., or at room temperature), to be positioned on to the dielectric membrane to form at least a further portion of the electronic device. This transfer process is described in more detail herein.

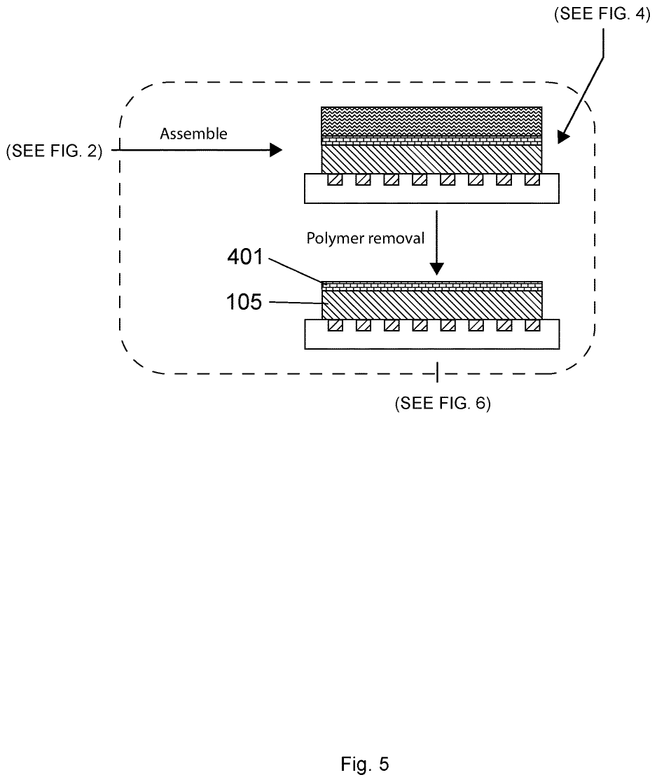

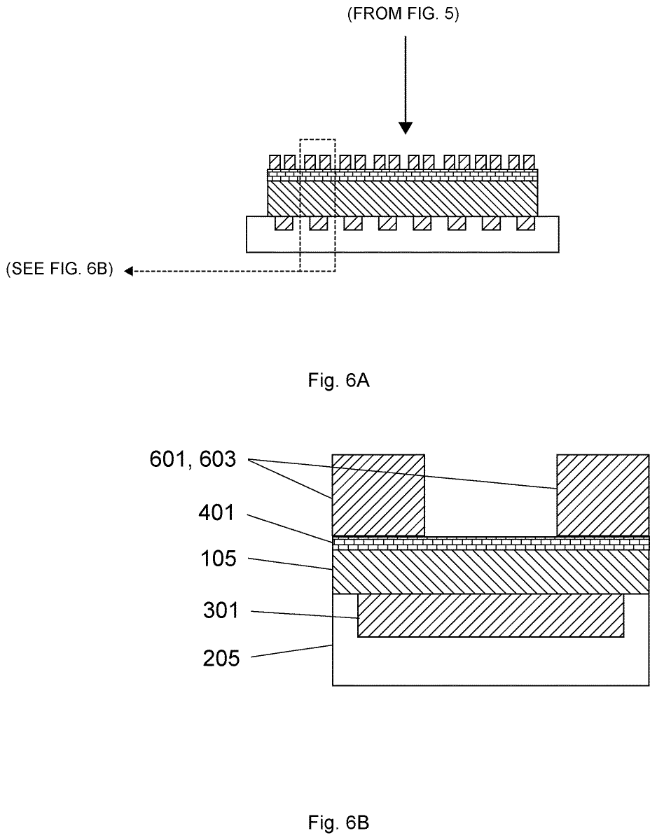

FIG. 5 shows a diagrammatic representation of process steps for integrating the monolayer stack onto the dielectric membrane, which was previously positioned on the target substrate. That is, a first portion of the electronic device is assembled with a further portion of the electronic device.

The monolayer stack formed from a combination of the polymer support layer 405 and the semiconductor channel layer 401 is assembled onto the dielectric membrane 105 that was positioned on the target substrate 205. Subsequently, the polymer support layer 405 is removed leaving the semiconductor channel layer 401 on top of the dielectric membrane 105, which is on the target substrate 205.

FIGS. 6A and 6B show diagrammatic representations of further process steps for forming an electronic device.

FIG. 6A shows the formation of further electrodes on the surface of the semiconductor channel layer 401. In this example, the electrodes formed are source and drain electrodes.

FIG. 6B shows a magnification of the hatched area shown in FIG. 6A indicating the different components of the electronic device, including the source electrode 601, drain electrode 603, gate electrode 301, target substrate 205, dielectric membrane 105 and semiconductor channel layer 401.

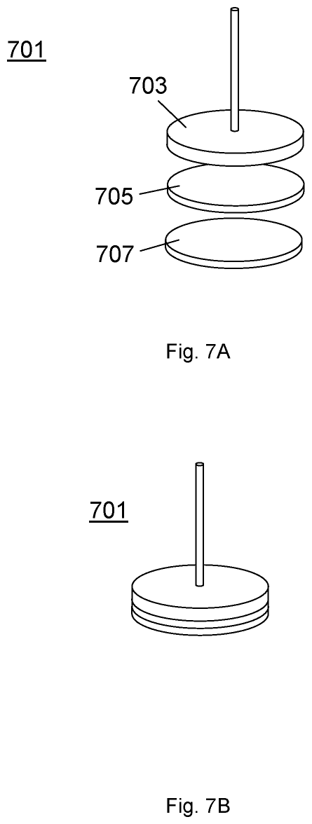

FIGS. 7A to 12 show an example of the process steps for forming a dielectric membrane on a solid-state substrate.

FIG. 7A shows an example of a transfer module 701 for transferring portions of the electronic device as it is processed. The transfer module 701 has a manipulator 703, a PDMS (polydimethylsiloxane) layer 705 and a PPC (polypropylene carbonate) layer 707 for transferring the portions of the electronic device during processing. The assembled transfer module 701 is shown in FIG. 7B.

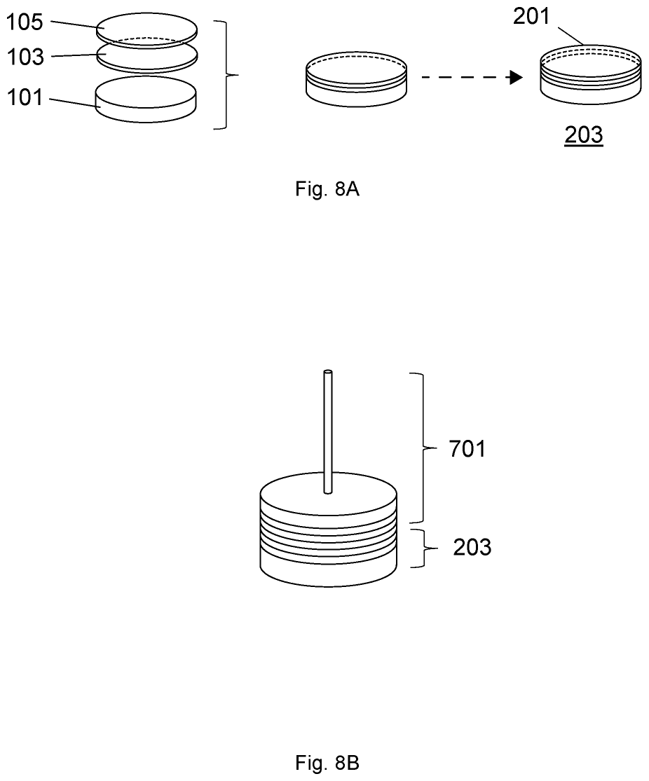

FIG. 8A depicts the dielectric membrane 105 and sacrificial layer 103 on the temporary substrate 101, as described herein with reference to FIG. 1, and also the addition of the polymer support layer 201, which is spin coated onto the dielectric membrane 105. The structure here is the layered sample 203

FIG. 8B shows the transfer module 701 picking up the layered sample 203 using a low temperature transfer process by contacting the PPC layer 707 and heating to approximately 110° C. to melt the PPC and cause the PPC to attach to the polymer support layer 201 of the layered sample 203. It will be understood that other suitable low temperature processes, between 0° C. and 150° C. (including room temperature), may also be used to transfer the layered sample.

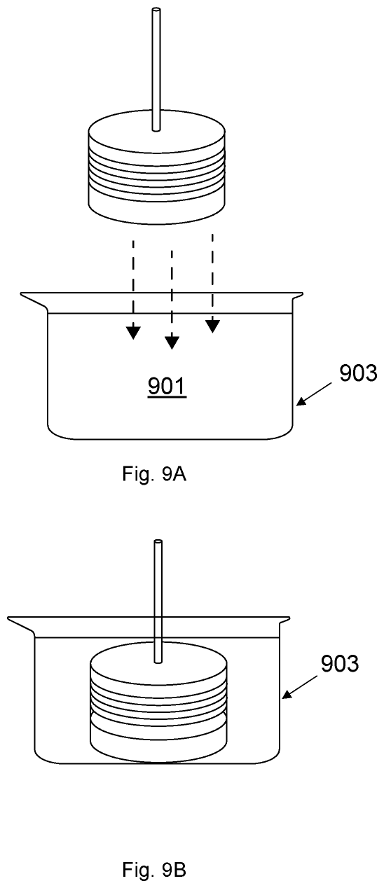

FIG. 9A shows the transfer module placing (e.g. immersing) the layered sample 203 into de-ionised water 901 in a receptacle 903.

FIG. 9B shows the sacrificial layer 103 in the layered sample dissolving in the de-ionised water, thus separating the temporary substrate 101 from the layered sample 203.

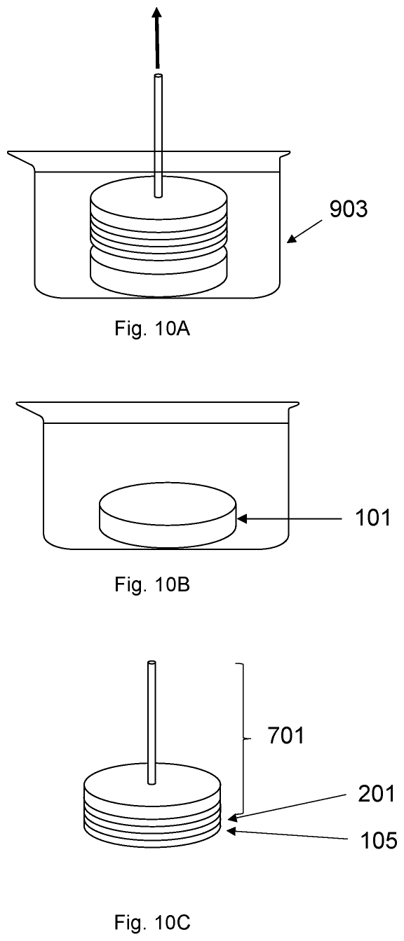

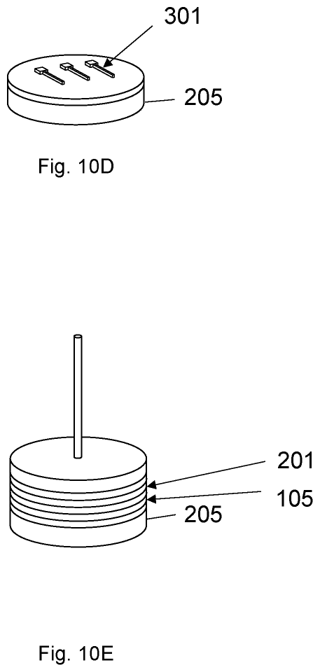

FIG. 10A shows the transfer module 701 retracting away from the receptacle 903 leaving behind the temporary substrate 101, as shown in FIG. 10B.

FIG. 10C shows the transfer module 701 with the remaining membrane stack of the polymer support layer 201 and the dielectric membrane 105.

FIG. 10D shows a target substrate 205 with electrodes 301 formed thereon.

FIG. 10E shows the transfer module 701 aligning the membrane stack and positioning the membrane stack onto the target substrate 205.

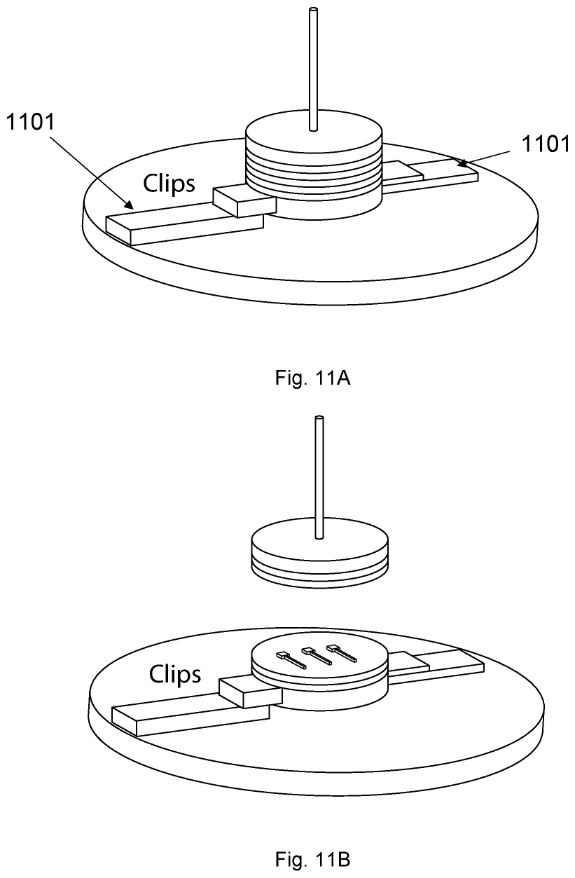

In FIG. 11A, the transfer module 701 transfers the membrane stack to a clamping device 1101 with clips 1103, which hold the membrane stack in position. The transfer module 701, using a low temperature process, heats the PPC to approximately 110° C. to melt the PPC and cause the polymer support layer 201 of the layered sample 203 to separate from the PPC. FIG. 11B shows the transfer module 701 retracting away from the membrane stack. It will be understood that other suitable low temperature processes, between 0° C. and 150° C. (including room temperature), may also be used to transfer the layered sample.

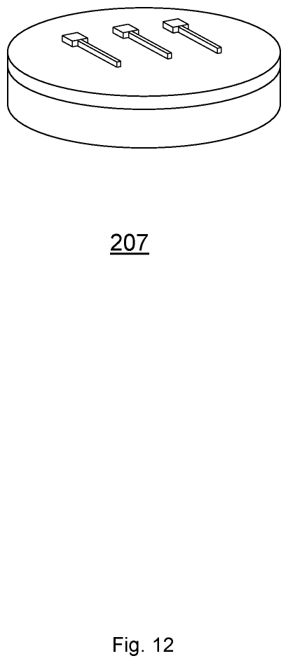

The membrane stack is then released from the clips and rinsed in acetone to remove the polymer support layer, leaving behind the dielectric membrane on the target substrate as portion 207 of the electronic device shown in FIG. 12.

The transfer process described herein with reference to the layered sample 203 may also be used to transfer the monolayer stack (401, 405) onto the dielectric membrane 105 (as referenced in FIGS. 4 and 5).

As a further example, a layered sample 203 and/or a monolayer stack (401, 405) may be transferred, moved or manipulated at a low temperature that is room temperature. For example, at room temperature a vacuum manipulator may be used instead of the transfer module 701 described herein. For example, the vacuum manipulator may hold a layered sample 203 or a monolayer stack (401, 405) in place using a vacuum suction plate by applying and removing suction between the plate surface and the layered sample 203 or monolayer stack (401, 405) to attach and release the layered sample 203 or monolayer stack (401, 405). Physical manipulation may also occur at room temperature where the layered sample 203 or monolayer stack (401, 405) is clamped or held by a manipulator to transfer, move or manipulate the layered sample 203 or monolayer stack (401, 405).

Non-limiting examples of how the dielectric membrane and semiconductor channel layer are formed are now provided.

The dielectric membrane is formed to have a low current leakage characteristic. The low current leakage is understood to be approximately Jₗₑₐₖ<10⁻² A/cm² for low-power applications, and Jₗₑₐₖ<10 A/cm² for high-power applications. Low power is understood to be in the range 10⁻⁷ A/cm² to 10⁻² A/cm². High power is understood to be in the range 10⁻² A/cm² to 10 A/cm².

The membrane is formed to have the characteristic of a high breakdown field, which is understood to be approximately E_{bd}>5 MV/cm.

According to some examples, the devices (e.g. transistors) using scalable chemical vapor deposition (CVD) techniques to form the MoS₂ layer and SrTiO₃ dielectric exhibit steep subthreshold swings (SS) down to ~70 mV dec⁻¹ and ON/OFF current ratios up to 10⁷, matching low-power specifications suggested by the latest International Roadmap for Devices and Systems (IRDS).

Further, according to examples described herein, the transparent and flexible devices (e.g. transistors) produced exhibit the same I-V semiconductor material behaviours after a cycle of a tensile bending strain of 0.54%. Further, the electronic device exhibits the same performance before, during and after flexing the device with a tensile bending strain of 0.54%.

The dielectric membrane is processed in order to minimize interfacial trapping states and suppress undesired impurity scattering effects.

The high-k gate dielectric membrane has natural high-permittivity and so facilitates the equivalent oxide thickness (EOT) shrinking into the sub 1 nm scale effortlessly, as well as moderating the deleterious impact when device downscaling.

According to one example, the dielectric membrane is prepared using pulsed laser deposition (PLD) as follows. A heterostructure is formed consisting of a sacrificial material on top the substrate and a high-k dielectric material on top of a sacrificial material. First, a single crystal SrTiO₃ (temporary) substrate with step-terrace topography is prepared by etching in buffered HF and subsequently annealing at the temperature from 800° C. to 1000° C. under an oxygen atmosphere. Prior to deposition, the temporary substrate is pre-annealed in-situ at the temperature from 750° C. to 950° C. with an oxygen partial pressure from 1×10⁻³ torr to 1×10⁻⁵ torr for 15 mins. Following the pre-anneal, the temperature is changed to between 750° C. and 950° C. and the water-soluble sacrificial material (Sr₃Al₂O₆) is deposited with a KrF excimer laser (248 nm) at a frequency of 1 Hz and energy density of 3.5 J/cm². After, epitaxial growth of a high-k dielectric membrane (SrTiO₃) on Sr₃Al₂O₆ is conducted at the temperature from 650° C. to 850° C. without changing the other deposition parameters. Finally, the heterostructure is cooled down to room temperature in an ambient environment.

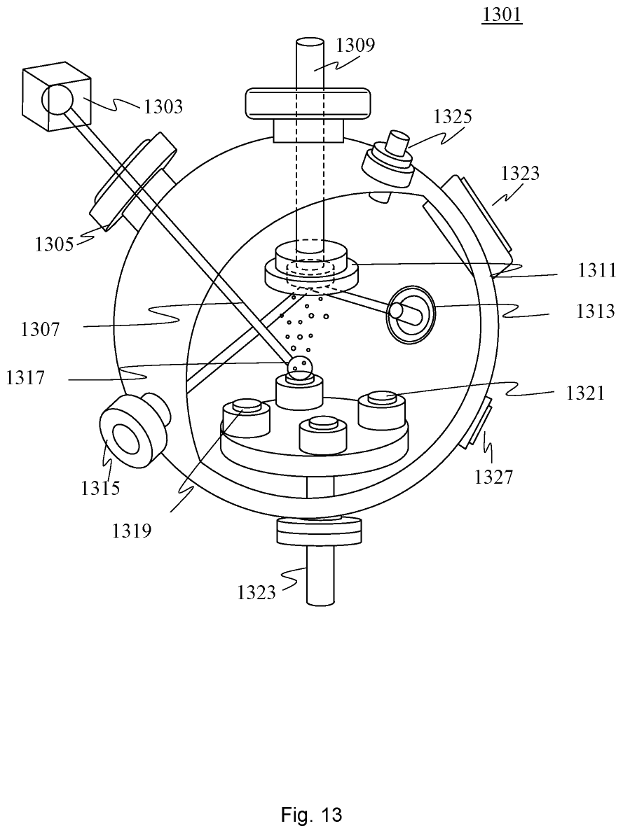

An example of a suitable PLD system is shown in FIG. 13 showing an external excimer laser source 1303 and a ultrahigh vacuum deposition chamber 1301. The pulsed laser beam 1307 generated from the excimer laser source 1303 focuses on either the Sr₃Al₂O₆ target 1319 or SrTiO₃ target 1319, respectively, in the ultrahigh vacuum chamber 1301 through the laser port 1305. A rotatable sample manipulator 1309 enables the sample in the chamber to be rotated on the sample stage 1311. A Reflection High-Energy Electron Diffraction (RHEED) gun 1313 is provided to generate an electron beam along with a RHEED screen 1315. The pulsed laser generates a plume 1317 of material. The Sr₃Al₂O₆ target 1319 and SrTiO₃ target 1321 are also placed in the chamber on a planetary target manipulator 1323 to deposit the materials onto the substrate. The system 1301 also includes a view port 1323, a pressure gauge 1325 and a pyrometer 1327 for the measurements of chamber pressure and substrate temperature.

It will be understood that the above process parameters are examples only and other suitable parameters may be used.

For example, the temperature range for the sacrificial layer deposition may be between 750° C. and 950° C. As another example, the laser energy density (fluence) for the sacrificial layer deposition may be between 2.4 J/cm² and 3.6 J/cm². Asa further example, the laser frequency for the sacrificial layer deposition may be between 1 and 5 Hz.

For example, the temperature range for the SrTiO₃ layer deposition may be between 650° C. and 850° C. As another example, the laser energy density (fluence) for the SrTiO₃ layer deposition may be between 2.4 J/cm² and 3.6 J/cm². As a further example, the laser frequency for the SrTiO₃ layer deposition may be between 1 and 5 Hz.

According to another example, the dielectric membrane may be prepared using oxide molecular beam epitaxy (OMBE). For example, the Sr₃Al₂O₆ (SAO) sacrificial layer 103 is first deposited on the commercial one-side polished (001) oriented SrTiO₃ (STO) substrate (temporary substrate 101) with oxide molecular beam epitaxy (OM BE, M600, DCA Instruments Oy, Finland) technique. Subsequently, STO film (dielectric membrane 105) is deposited on top of the SAO sacrificial layer 103 in the same OMBE chamber. The chamber is kept at a base pressure of 10⁻¹⁰ torr and oxygen is supplied by a plasma or ozone source and controlled through a leak valve to maintain the pressure of 10⁻⁷ torr. The flux rates of high-purity metallic Sr, Al, and Ti sources are initially calibrated by using a quartz crystal microbalance (QCM). Using the real-time reflection high-energy electron diffraction (RHEED) oscillations, the flux rates of Sr/Al and Sr/Ti can be precisely adjusted to the ratios of 3:2 and 1:1, with a flux rate of 9.07×10¹³ cm⁻² s⁻¹ for Sr and Ti, and 1.36×10¹³ cm⁻² s⁻¹ for Al, respectively. The substrate temperature is held between 650° C. and 850° C. during the deposition of SAO sacrificial layer, and then lowered to the temperature between 550° C. to 750° C. for the deposition of dielectric STO film. The entire growth including the film thickness are monitored by the real-time RHEED oscillation.

It will be understood that the above process parameters are examples only and other suitable parameters may be used.

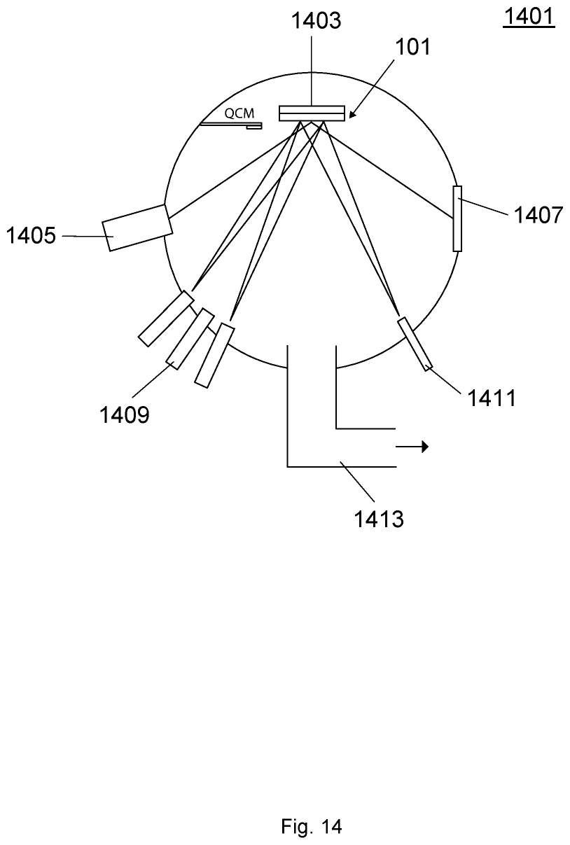

An example of a suitable OMBE system 1401 is shown in FIG. 14. Th system shows the temporary substrate 101 on a platform 1403 in the OMBE chamber 1401, with a RHEED gun 1405, a RHEED screen 1407, Effusion cells 1409, an oxygen plasma supply 1411, a quartz crystal microbalance (QCM) and pipework 1413 to the roughing pump and cryo-pump to reach required vacuum levels.

According to another example, the dielectric membrane may be prepared using chemical vapour deposition (CVD). For example, the Sr₃Al₂O₆ (SAO) sacrificial layer is first deposited on the SrTiO₃ substrate (temporary substrate) at the temperature of 700-900° C. with the deposition pressure of 1-100 torr. Many different precursors may be used, as listed in Table 1, to deposit the SAO sacrificial layer. The ratio of Sr/Al is determined by the stoichiometric atomic ratio of 3:2 and this can be controlled by the flow rates of the Sr and Al precursor vapours. Oxygen is provided by oxygen gas, nitrous oxide, or water. The thickness of the SAO sacrificial layer can be controlled by manipulating the deposition time and/or the optimized precursor flow rates. Subsequently, the dielectric membrane SrTiO₃ is deposited on top of the SAO sacrificial layer with the precursors listed in Table 1 at the deposition temperature of 750-950° C. (CVD) or 250-350° C. [Atomic Layer deposition (ALD), followed by 500-900° C. post-annealing] with the deposition pressure of 1-100 torr. The ratio of Sr/Ti in 1:1 is controlled by the flow rates of the Sr and Ti precursor vapours in 1:1. Similarly, the oxygen is provided by either oxygen gas, nitrous oxide, or water and the time is used to control the thickness of the deposited STO film.

TABLE 1
below shows the precursors for the deposition of Sr₃
Al₂O₆ and SrTiO₃ Films for the above described CVD technique.

Strontium
Strontium bis(N,N,N′,N′,N″-pentamethyldiethylenetriamine)bis[BREW]
Bis(2,2,6,6-tetramethyl-3,5-heptanedionato)strontium hydrate
Strontium hexafluoroacetylacetonate
Strontium bis(tri-isopropylcyclopentadienyl)
Titanium
Titanium(IV) isopropoxide
Titanium(IV) chloride
Titanium(IV) fluoride
Titanium(IV) n-butoxide
Titanium(IV) t-butoxide
Titanium(IV) ethoxide
Tetrakis(diethylamino)titanium(IV)
Titanium(IV) (di-i-propoxide)bis[BREW]
(Trimethyl)pentamethylcyclopentadienyltitanium(IV)
Aluminum
Aluminum acetylacetonate
Aluminum s-butoxide
Aluminum i-propoxide
Aluminum hexafluoroacetylacetonate
Trimethylaluminum
Oxygen
Water
Nitrous oxide
Oxygen

It will be understood that the above process parameters are examples only and other suitable parameters may be used.

The composition of the sacrificial layers can be summarised as M₃Al₂O₆, where M can be Ca, Sr, and Ba, and the composite of any two of the elements.

The sacrificial layers can also be made with SrRuO₃, La_{0.7}Sr_{0.3}MnO₃, YBa₂Cu₃O₇ and other oxide layers, which can be dissolved in etchants including NalO₄, HCl and others.

There are a number of commercially available substrates for the fabrication of the freestanding single crystal oxide membranes including SrTiO₃, LaAlO₃, NdGaO₃, (LaAlO₃)0.3-(SrAl_{0.5}Ta_{0.5}O₃)0.7 and other oxide substrates.

The dielectric membrane and semiconductor channel layer form a van der Waals interface between the dielectric membrane and the semiconductor channel layer. Further, another van der Waals interface is formed between the dielectric membrane and the gate electrode.

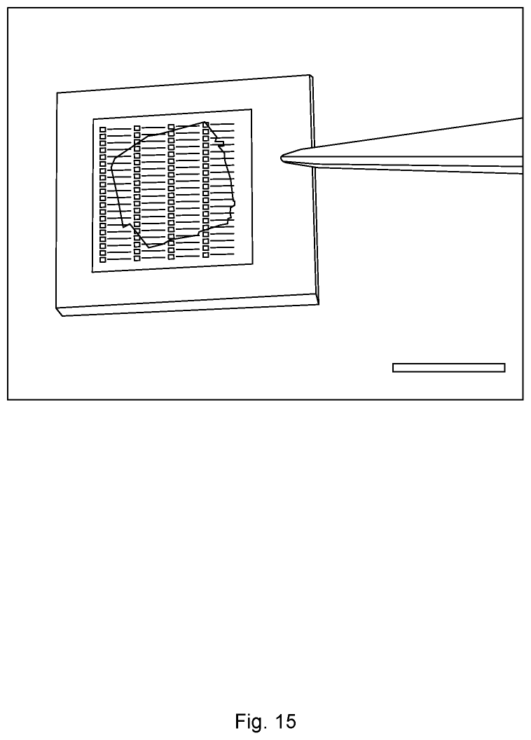

FIG. 15 shows a photo of a dielectric membrane being transferred (mechanically) where the transferred millimeter-scale FS-STO membrane is shown on a pre-pattern Si/SiO₂ substrate. The scale bar indicates 5 mm.

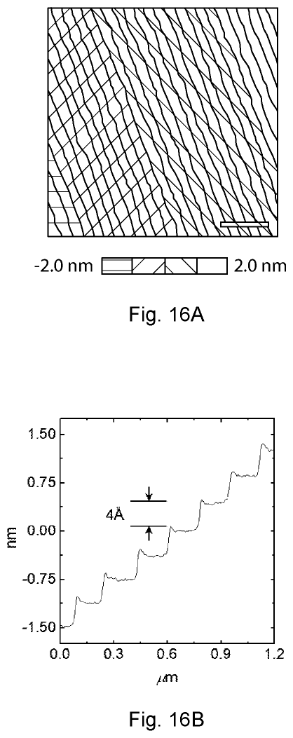

FIGS. 16A and 16B show atomic force microscopy image of the as-grown SrTiO₃ film, indicating an atomically smooth surface with unit cell step terraces. The white scale bar in FIG. 16A indicates 1 μm.

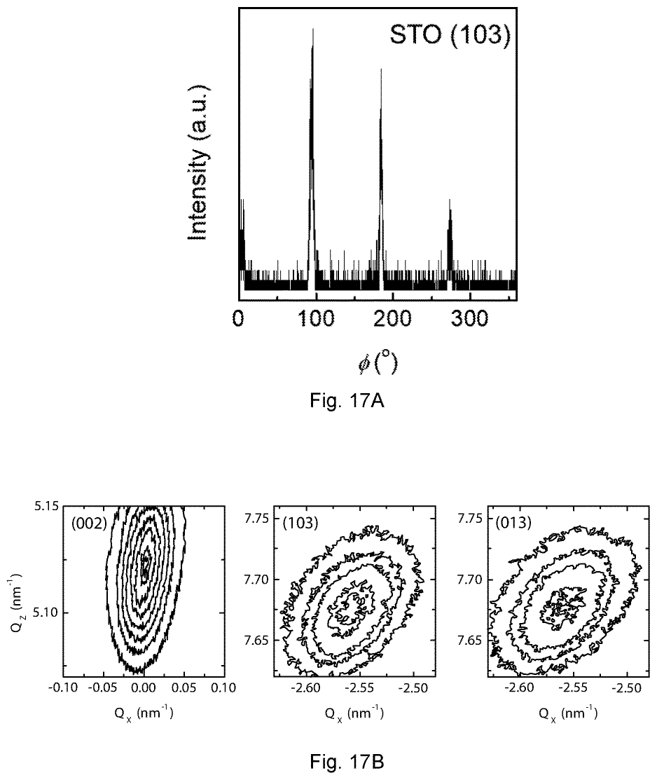

FIG. 17A shows an XRD Φ-scan of (103) reflections of 80 u.c. STO film transferred to a Si substrate. FIG. 17B shows reciprocal space mapping (RSM) of the transferred 80 u.c. STO film around (002), (103), and (013) planes.

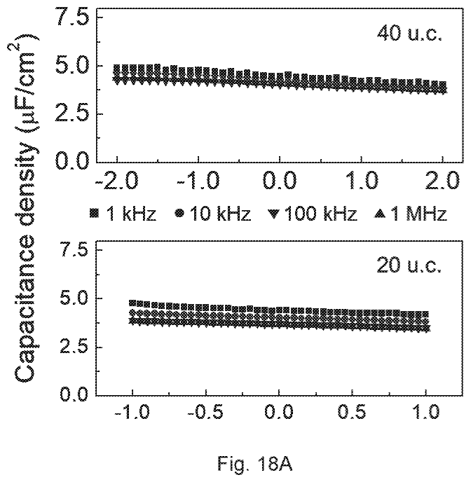

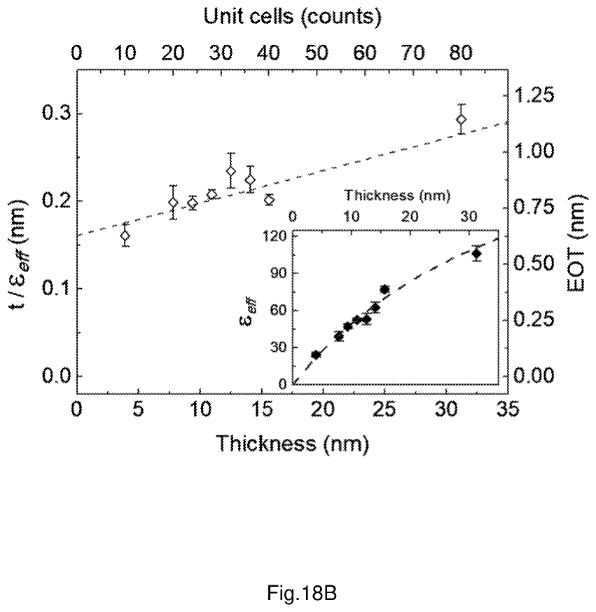

FIG. 18A shows voltage-dependent capacitance density (C-V) measurements for metal-insulator-metal (MIM) devices of 40 u.c. and 20 u.c. STO thin films at four different frequencies of 1 kHz, 10 kHz, 100 kHz and 1 M Hz. FIG. 18B shows t/ε_{eff}, where t is the thickness of the free-standing STO membrane, and ε_{eff} is its effective permittivity, and equivalent oxide thickness (EOT) as a function of various STO thicknesses measured from MIM capacitors. The inset displays ε_{eff} as a function of STO thickness. Both dashed lines indicate a theoretical curve fitting.

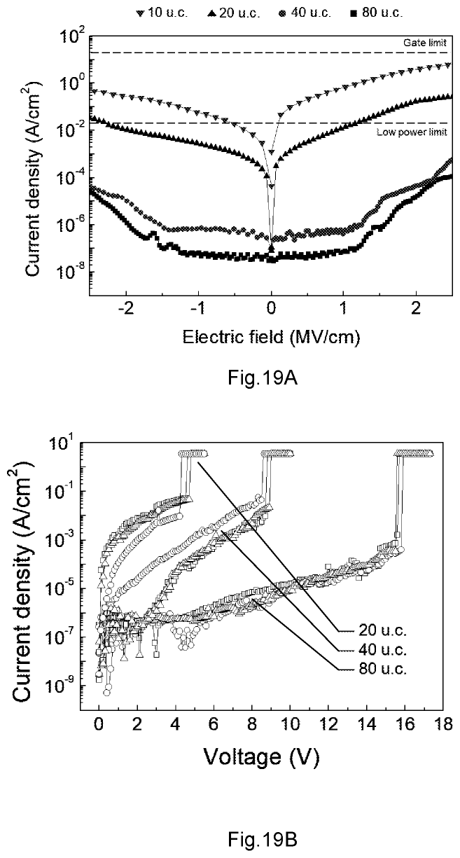

FIG. 19A shows electric field-dependent leakage current density of STO films with various unit-cell thicknesses. The dashed lines mark the limits for relative applications including gate limit and low power limit. FIG. 19B shows breakdown characteristics of STO layers with various thicknesses. The average breakdown fields were calculated as 5.04 MV/cm (80 u.c.), 5.64 MV/cm (40 u.c.), and 5.86 MV/cm (20 u.c.).

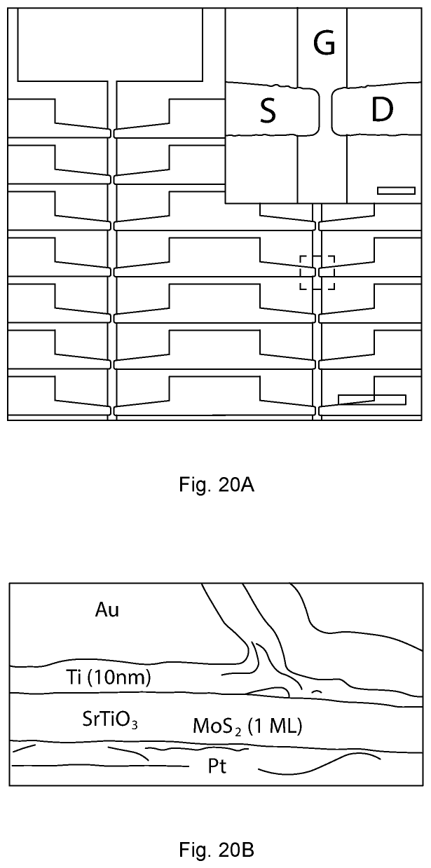

FIG. 20A shows an optical micrograph of batch-fabricated FET arrays. Inset shows the magnified image of the dashed square portion. The scale bars are 100 μm and 10 μm (inset) respectively. FIG. 20B shows cross-sectional scanning transmission electron microscope (STEM) image and the corresponding energy-dispersive X-ray spectroscopy (EDS) mapping obtained in the contact-channel area.

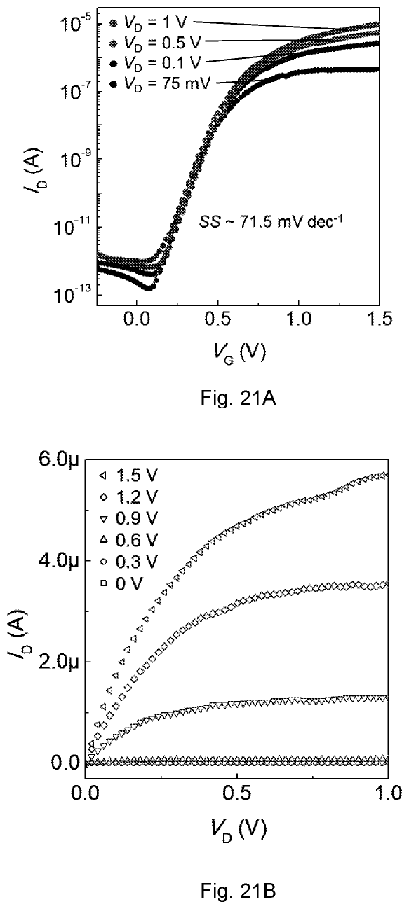

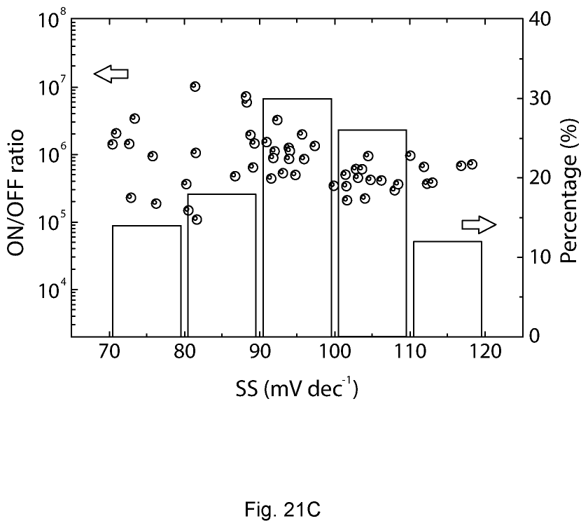

FIG. 21A displays transfer characteristics (I_{D}-V_{G}) of monolayer MoS₂ FET with the same structure shown in FIG. 6B. FIG. 21B shows output characteristics (I_{D}-V_{D}) of the same device. FIG. 21C shows scatter distribution (black) of recorded ON/OFF current ratios and subthreshold swing (SS) values, and statistical histogram of SS from 50 devices.

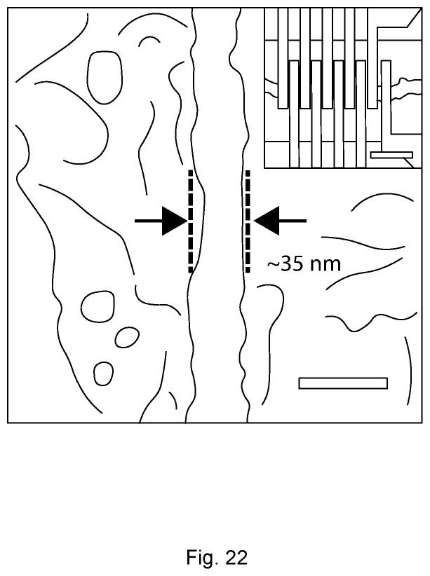

FIG. 22 shows a scanning electron microscope (SEM) image of the device with a channel length of 35 nm. Inset shows the optical micrograph of the associated devices. Scale bars indicate 50 nm and 1 μm (inset).

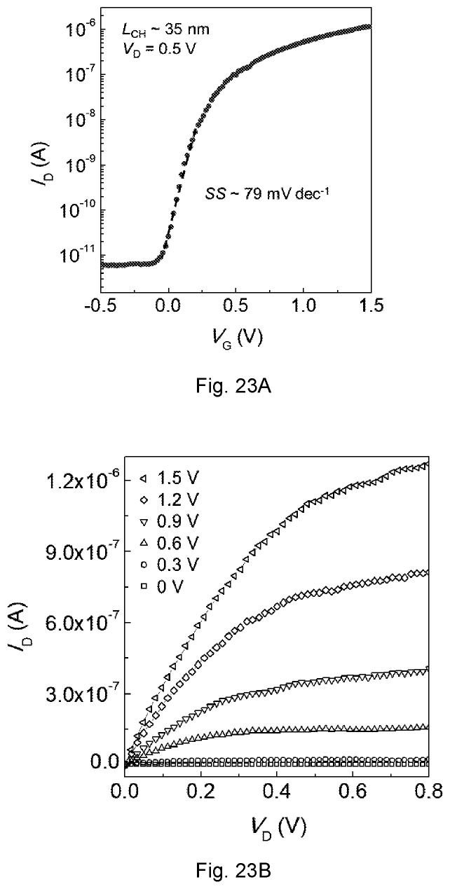

FIG. 23A shows I_{D}-V_{G} characterization of the device shown in FIG. 22. FIG. 23B shows I_{D}-V_{D} output curves of the same device.

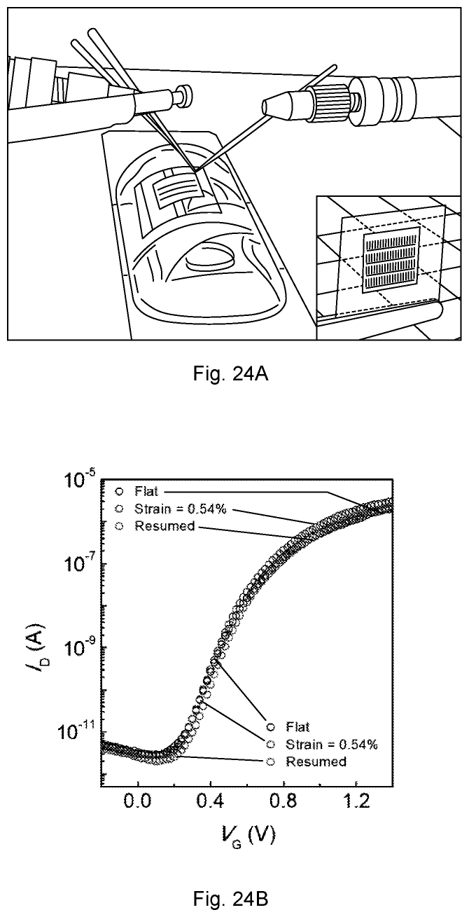

FIG. 24A shows photograph of experiment setup for mechanical bending of MoS₂ FETs, where the samples are bent to a tensile strain of 0.54%. Inset is the photograph of MoS₂ FET arrays on flexible and transparent PET substrate. FIG. 24B shows measured transfer characteristics of the device under flat, strained, and resumed conditions.

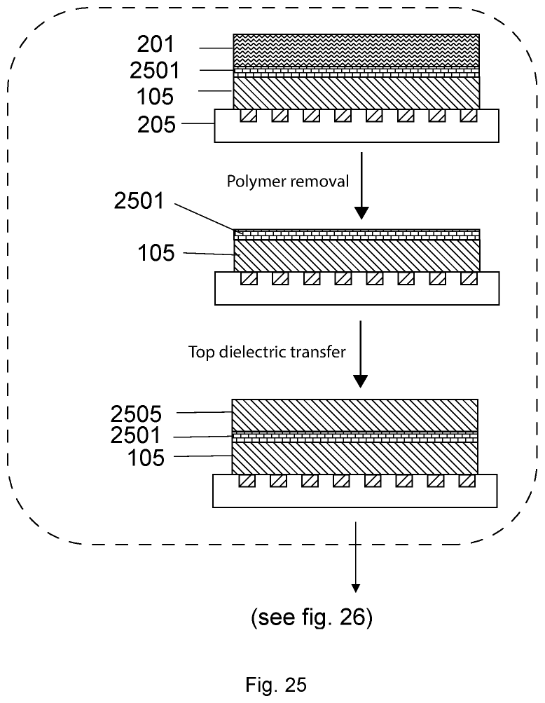

FIG. 25 shows a further example of process steps used to manufacture a dual-gate FET device incorporating the free-standing membrane as described herein.

Prior to forming the polymer support layer 201 on top of the high-k dielectric membrane layer 105 (as described with reference to FIG. 2), a semiconductor channel layer 2501, formed from a material such as MoS₂ for example, is formed on top of the high-k dielectric membrane layer 105. The three layers 105, 2501 and 201 are transferred to the target substrate 205 using any suitable transfer method as described herein. The polymer layer 201 is removed, as described herein.

An additional high-k dielectric membrane 2505 is then formed and transferred to be positioned on top of the semiconductor channel layer 2501. The additional high-k dielectric membrane 2505 may be formed using any of the techniques as described herein.

Therefore, as shown in FIG. 25, after integrating the monolayered semiconductor onto the dielectric membrane, an additional dielectric membrane is transferred onto the stack.

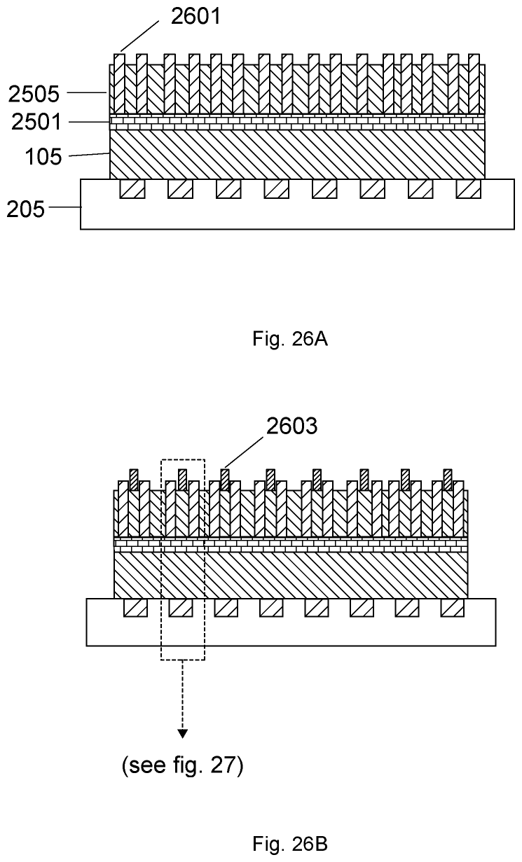

FIGS. 26A and 26B show the process steps for forming top gate electrodes for the dual-gate FET device.

An etch process is applied to form source and drain contact holes through the additional high-k dielectric membrane 2505. One or more suitable etch processes may be used, as is known in the art.

Source and drain electrodes 2601 are formed using one or more suitable deposition techniques, as is known in the art.

Top gate electrodes 2603 are then formed using one or more suitable deposition techniques, as is known in the art.

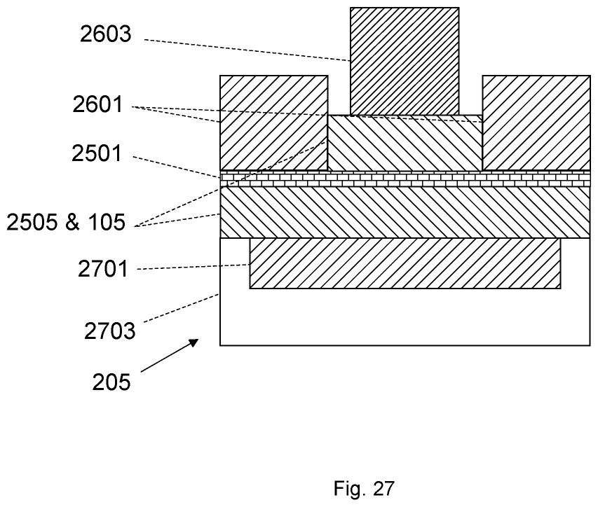

FIG. 27 shows a magnified view of the section highlighted in FIG. 26B. In this view, the top gate electrode 2603, source and drain electrodes 2601, high-k dielectric membranes (105, 2505), semiconductor channel layer 2501 and target substate 205 (which in this example is formed with a bottom gate electrode 2701 and a solid state substrate 2703) are clearly shown.

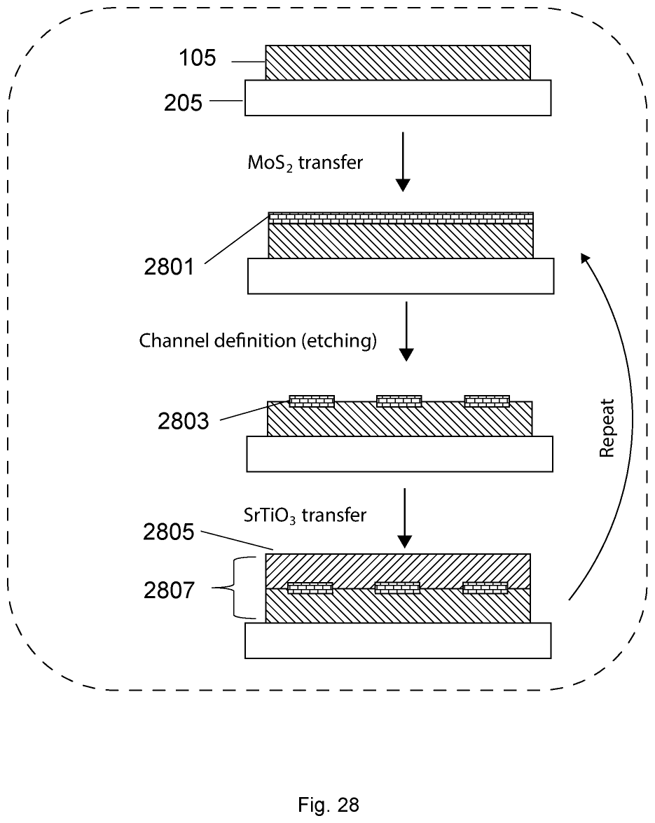

FIG. 28 shows a further example of process steps used to manufacture a gate-all-around (GAA) device incorporating the free-standing membrane as described herein.

In FIG. 28 after the high-k dielectric membrane 105 has been transferred to the target substrate 205, a semiconductor channel layer 2801, formed from a material such as MoS₂ for example, is formed on top of the high-k dielectric membrane layer 105. One or more suitable etching processes, as known in the art, are applied to etch channels into the semiconductor channel layer 2801 forming nanosheet channels 2803. An additional high-k dielectric membrane 2805 is then formed and transferred to be positioned on top of the nanosheet channels 2803 to form a gate-all-around (GAA) structure 2807. The additional high-k dielectric membrane 2805 may be formed using any of the techniques as described herein.

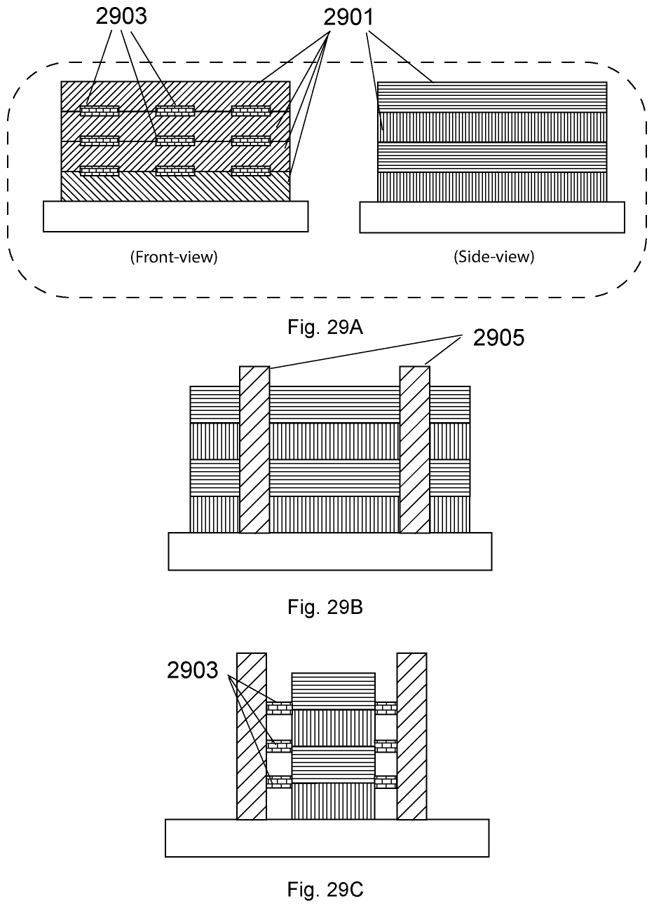

FIG. 29A shows a front view and side view of the gate-all-around (GAA) structure after repeating the steps in FIG. 28 to form multiple layers of high-k dielectric membranes 2901 with nanosheet channels 2903.

FIG. 29B shows a side view of the gate-all-around (GAA) structure with source and drain electrodes 2905 that have been formed using one or more suitable etching processes, as known in the art, to etch a hole and deposition processes, as known in the art, to deposit the electrodes.

FIG. 29CB shows a side view of the gate-all-around (GAA) structure with selectively etched portions of the high-k dielectric using one or more suitable etching processes, as known in the art, to selectively etch the dielectric material to expose the nanosheet channels 2903.

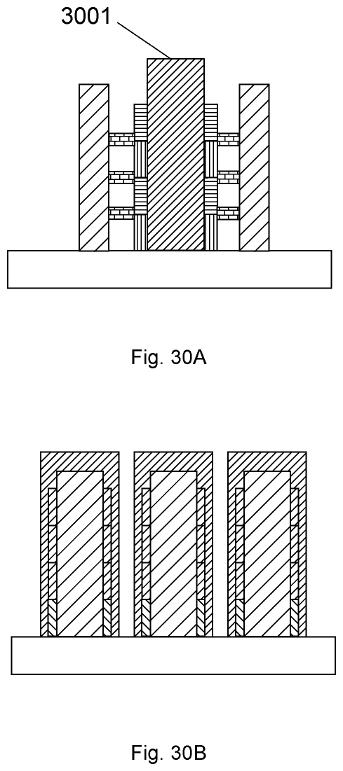

FIG. 30A shows a side view of the gate-all-around (GAA) structure with a gate electrode 3001 that have been formed using one or more suitable etching processes, as known in the art, to etch a hole through the dielectric and deposition processes, as known in the art, to deposit the gate electrode. FIG. 30B shows a front view of the device in FIG. 30A.

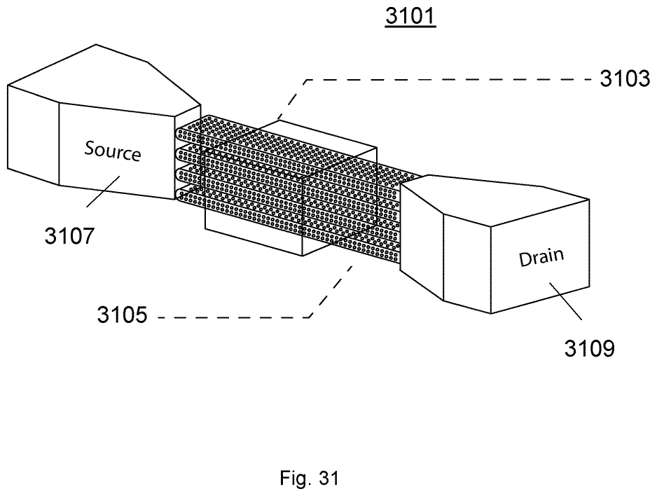

FIG. 31 shows a three dimensional perspective view of a gate-all-around device 3101, with a high-k gate-all-around (GAA) stack 3103 and a nanosheet channel stack 3105 with a source 3107 and drain 3109.

As described herein, there is provided an electronic device that has: a non conductive solid-state substrate; a plurality of electrodes; a high-k dielectric membrane, wherein the dielectric membrane is formed as a free-standing membrane; and a semiconductor channel layer; wherein the dielectric membrane and semiconductor channel layer form a van der Waals interface between the dielectric membrane and the semiconductor channel layer and another van der Waals interface between the dielectric membrane and at least one of the electrodes.

The dielectric membrane may be a crystalline oxide membrane formed from metal oxide, metal nitride, perovskite or polymer. The dielectric membrane may be elastic. The dielectric membrane may have a thickness from 1-unit cell to 100-unit cells. The dielectric membrane may have a low current leakage and a high breakdown field. The dielectric membrane may be formed as an atomic smooth and monocrystalline membrane. The dielectric membrane may be formed from SrTiO₃, LaAlO₃, BaTiO₃, BiTiO₃, BiFeO₃, CaMnO₃, KTaO₃, BaZrO₃, PbZrₓTi₍₁₋ₓ₎O₃, Al₂O₃, CeO₂, MgO, TiO₂, HfO₂, ZrO₂, Ta₂O₅, La₂O₃, Y₂O₃ or Ga₂O₃, AlN and TiN or their modified compounds, other oxides or nitrides. The dielectric membrane may comprise a single crystal perovskite oxide thin film with a thickness from 1 unit cell to 100-unit cells. The dielectric membrane may comprise a dielectric perovskite oxide membrane formed from monocrystalline SrTiO₃ membrane with a thickness of 40-unit cells.

The electronic device may be transparent and/or flexible.

The semiconductor channel layer may be a black phosphorous, or a transition metal dichalcogenide based semiconductor of the type MX₂, where M is a transition metal atom selected from Mo, W, Ti, Zr, Hf, Pd, Pt and their alloys, or is a 2D material of Bi₂O₂X where X is a chalcogen atom selected from S, Se, Te and their mixtures. The transition metal dichalcogenide may be a two-dimensional transition metal dichalcogenide with a thickness range of between a monolayer and 50 multilayers. The two-dimensional transition metal dichalcogenide may be a monolayered MoS₂.

The semiconductor channel layer may be formed from an oxide-based semiconductor material comprising Bi₂O₂Se, In₂Ga₂ZnO₇ (IGZO), ZnO or TiO₂ or others.

The solid-state substrate may be transparent and may be formed from glass, quartz, a wide bandgap semiconductor selected from ZnO and TiO₂, or an oxide selected from Al₂O₃, MgO and SrTiO₃.

The solid-state substrate may be flexible and may be formed from paper, polymer or other organic substance, an insulator coated metallic foil, human tissue, or biological tissue.

The solid-state substrate may be transparent and flexible and may be formed from polyethylene terephthalate (PET), polycarbonate, PMMA or Acrylic, Amorphous Copolyester (PETG), Polyvinyl Chloride, Liquid Silicone Rubber (LSR), Cyclic Olefin Copolymer (COC), Polyethylene (PE), Ionomer Resin, Polypropylene, Fluorinated Ethylene Propylene (FEP), Styrene Methyl Methacrylate (SMMA), Polystyrene, Styrene Acrylonitrile Resin (SAN), Methyl Methacrylate Acrylonitrile Butadiene Styrene or mica.

The electronic device may be a field effect transistor and the electrodes may comprise gate, source and drain electrodes, and the another van der Waals interface may be between the dielectric membrane and the gate electrode.

The semiconductor channel layer, the dielectric membrane, the electrodes and the substrate may be assembled together at a low temperature of between 0° C. and 150° C. The semiconductor channel layer, the dielectric membrane, the electrodes and the substrate may be assembled together at room temperature.

The electronic device may be formed using a method comprising the steps of assembling the semiconductor channel layer, the dielectric membrane, the electrodes and the substrate at a low temperature of between 0° C. and 150° C. The low temperature may be room temperature.

Also described is a method of forming at least a portion of an electronic device from a layered sample, wherein the layered sample comprises a membrane stack that has a polymer support layer formed on a high-k dielectric membrane, the membrane stack formed on a sacrificial layer, and the sacrificial layer formed on a temporary substrate, the method has the steps of, at a low temperature of between 0° C. and 150° C.: immersing the layered sample into de-ionised water for removing the sacrificial layer and separating the temporary substrate from the membrane stack; removing the membrane stack from the de-ionised water; positioning the membrane stack on a target substrate, wherein the target substrate comprises electrodes; and removing the polymer support layer from the membrane stack leaving the dielectric membrane formed on the target substrate to form at least a portion of the electronic device.

The method may also have the steps of: depositing a semiconductor channel layer on a further temporary substrate; depositing a further polymer support layer on to the semiconductor channel layer, wherein the further polymer support layer and semiconductor channel layer form a monolayer stack; delaminating the further temporary substrate from the monolayer stack; and transferring, at the low temperature, the monolayer stack onto the dielectric membrane to form at least a further portion of the electronic device.

The low temperature may be room temperature for at least one of the steps in the above method.

The method may also have the step of depositing further electrodes to form the electronic device.

The dielectric membrane may have a dielectric constant of greater than 10 and is formed using one of a Physical Vapour Deposition (PVD) process, a Chemical Vapour Deposition (CVD) process, a Molecular Beam Epitaxy (MBE) process and Thermal Evaporation. The CVD process may use one of a Plasma Enhanced (PE) CVD process, Plasma CVD process, Metalorganic CVD (MOCVD), and Metal Oxide (MO) CVD process.

An electronic device formed by the above method steps is also disclosed.

Further details of results of measurements taken during simulations of the devices described herein can be found in a paper published by inventors Huang, J K., Wan, Y., Chi, J. et al. High-κ perovskite membranes as insulators for two-dimensional transistors. Nature 605, 262-267 (2022), which is hereby incorporated by reference in its entirety.

### INDUSTRIAL APPLICABILITY

The arrangements described are applicable to semiconductor device fabrication industries.

The foregoing describes only some embodiments of the present invention, and modifications and/or changes can be made thereto without departing from the scope and spirit of the invention, the embodiments being illustrative and not restrictive.

In the context of this specification, the word “comprising” means “including principally but not necessarily solely” or “having” or “including”, and not “consisting only of”. Variations of the word “comprising”, such as “comprise” and “comprises” have correspondingly varied meanings.

1. An electronic device comprising:
a non-conductive solid-state substrate;
a plurality of electrodes;
at least one high-k dielectric membrane, wherein the dielectric membrane is formed as a free-standing membrane; and
at least one semiconductor channel layer;
wherein the dielectric membrane and semiconductor channel layer form a van der Waals interface between the dielectric membrane and the semiconductor channel layer.

2. The electronic device of claim 1, wherein there is a further van der Waals interface between the dielectric membrane and at least one of the electrodes

3. The electronic device of claim 1, wherein the dielectric membrane is a crystalline oxide membrane formed from metal oxide, metal nitride, perovskite or polymer, or
wherein the dielectric membrane is a freestanding single crystal membrane; or
wherein the dielectric membrane is elastic; or
wherein the dielectric membrane has a thickness from 1-unit cell to 100-unit cells; or
wherein the dielectric membrane has a low current leakage and a high breakdown field.

4-6. (canceled)

7. The electronic device of claim 1, wherein the device is transparent and/or flexible.

8. (canceled)

9. The electronic device of claim 1, wherein the semiconductor channel layer is a black phosphorous, or a transition metal dichalcogenide based semiconductor of the type MX₂, where M is a transition metal atom selected from Mo, W, Ti, Zr, Hf, Pd, Pt and their alloys, or is a 2D material of Bi₂O₂X where X is a chalcogen atom selected from S, Se, Te and their mixtures.

10. The electronic device of claim 9, wherein the transition metal dichalcogenide is a two-dimensional transition metal dichalcogenide with a thickness range of between a monolayer and 50 multilayers.

11. The electronic device of claim 10, wherein the two-dimensional transition metal dichalcogenide is a monolayered MoS₂.

12. The electronic device of claim 1, wherein the semiconductor channel layer is formed from an oxide-based semiconductor material comprising Bi₂O₂Se, In₂Ga₂ZnO₇ (IGZO), ZnO or TiO₂ or others.

13. The electronic device of claim 1, wherein the dielectric membrane is formed as an atomic smooth and monocrystalline membrane, or
wherein the dielectric membrane is formed from SrTiO₃, LaAlO₃, BaTiO₃, BiTiO₃, BiFeO₃, CaMnO₃, KTaO₃, BaZrO₃, PbZrₓTi₍₁₋ₓ₎O₃, Al₂O₃, CeO₂, MgO, TiO₂, HfO₂, ZrO₂, Ta₂O₅, La₂O₃, Y₂O₃ or Ga₂O₃, AlN and TiN or their modified compounds, other oxides or nitrides, or
wherein the dielectric membrane is formed from two or more of the following compounds: SrTiO₃, LaAlO₃, BaTiO₃, BiTiO₃, BiFeO₃, CaMnO₃, KTaO₃, BaZrO₃, PbZrₓTi₍₁₋ₓ₎O₃, Al₂O₃, CeO₂, MgO, TiO₂, HfO₂, ZrO₂, Ta₂O₅, La₂O₃, Y₂O₃, Ga₂O₃, AlN, TiN and with the configuration of a superlattice or from mechanically or physically stacking the individual dielectric membranes, or
wherein the dielectric membrane comprises a perovskite oxide thin film with a thickness from 1 unit cell to 100-unit cells, or
wherein the dielectric membrane comprises a dielectric perovskite oxide membrane formed from monocrystalline SrTiO₃ membrane with a thickness of 40-unit cells.

14-17. (canceled)

18. The electronic device of claim 1, wherein the solid-state substrate is transparent and is formed from glass, quartz, a wide bandgap semiconductor selected from ZnO and TiO₂, or an oxide selected from Al₂O₃, MgO and SrTiO₃, or
wherein the solid-state substrate is flexible and is formed from paper, polymer or other organic substance, an insulator coated metallic foil, human tissue, or biological tissue, or
wherein the solid-state substrate is transparent and flexible and is formed from polyethylene terephthalate PET), polycarbonate, PMMA or Acrylic, Amorphous Copolyester PETG), Polyvinyl Chloride, Liquid Silicone Rubber (LSR), Cyclic Olefin Copolymer COC), Polyethylene PE), Ionomer Resin, Polypropylene, Fluorinated Ethylene Propylene FEP), Styrene Methyl Methacrylate SMMA), Polystyrene, Styrene Acrylonitrile Resin SAN), Methyl Methacrylate Acrylonitrile Butadiene Styrene or mica.

19-20. (canceled)

21. The electronic device of claim 1, wherein the electronic device is a field effect transistor and the electrodes comprise gate, source and drain electrodes, and a van der Waals interface is between the dielectric membrane and the gate electrode, and another van der Waals interface is between the dielectric membrane and at least one of the electrodes.

22. The electronic device of claim 1, wherein the semiconductor channel layer, the dielectric membrane, the electrodes and the substrate are assembled together at a low temperature of between 0° C. and 150° C.

23. The electronic device of claim 22, wherein the semiconductor channel layer, the dielectric membrane, the electrodes and the substrate are assembled together at room temperature.

24. A method of forming the electronic device of claim 1 comprising the steps of assembling the semiconductor channel layer, the dielectric membrane, the electrodes and the substrate at a low temperature of between 0° C. and 150° C., and preferably where the low temperature is room temperature.

25. (canceled)

26. A method of forming at least a portion of an electronic device from a layered sample, wherein the layered sample comprises a membrane stack comprising a support layer formed on a high-k dielectric membrane, the membrane stack formed on a sacrificial layer, and the sacrificial layer formed on a temporary substrate, the method comprising the steps of, at a low temperature of between 0° C. and 150° C.:
immersing the layered sample into a liquid for removing the sacrificial layer and separating the temporary substrate from the membrane stack;
removing the membrane stack from the liquid;
positioning the membrane stack on a target substrate, wherein the target substrate comprises electrodes; and
removing the support layer from the membrane stack leaving the dielectric membrane formed on the target substrate to form at least a portion of the electronic device.

27. The method of claim 26 further comprising the steps of:
depositing a semiconductor channel layer on a further temporary substrate;
depositing a further polymer support layer on to the semiconductor channel layer, wherein the further polymer support layer and semiconductor channel layer form a monolayer stack;
delaminating the further temporary substrate from the monolayer stack; and
transferring, at the low temperature, the monolayer stack onto the dielectric membrane to form at least a further portion of the electronic device.

28. The method of claim 267, wherein the low temperature is room temperature for at least one of the steps.

29. The method of claim 26 further comprising the step of depositing further electrodes to form the electronic device.

30. The method of claim 26, wherein the dielectric membrane has a dielectric constant of greater than 10 and is formed using one of a Physical Vapour Deposition (PVD) process, a Chemical Vapour Deposition (CVD) process, a Molecular Beam Epitaxy (MBE) process and Thermal Evaporation.

31. The method of claim 30, wherein the CVD process uses one of a Plasma Enhanced (PE) CVD process, Plasma CVD process, Metalorganic CVD (MOCVD), and Metal Oxide (MO) CVD process.

32. The method of claim 26, wherein the support layer is a polymer support layer or an inorganic support layer.

33. (canceled)

34. The method of claim 26, wherein the liquid is selected from the group consisting of de-ionised water, etchant, and acid.

35. (canceled)

36. The method of claim 26, wherein the target substrate comprises a semiconductor layer instead of the electrodes, or the electrodes and a semiconductor layer.

37. An electronic device formed by the method of claim 26.
